(19) United States
(12) Patent Application Publication
(10) Pub. No.: US 2026/0085397 A1
(43) Pub. Date: Mar. 26, 2026

(54) Substrates with Hard Coats

(71) Applicant: Apple Inc., Cupertino, CA (US)

(72) Inventors: Maxim B Kelman, Los Altos, CA (US); James R Wilson, Saratoga, CA (US); Tyler R Roschuk, Morgan Hill, CA (US); Hsin-Wei Huang, Tokyo (JP)

(21) Appl. No.: 19/301,735

(22) Filed: Aug. 15, 2025

Related U.S. Application Data
(60) Provisional application No. 63/698,429, filed on Sep. 24, 2024.

(51) Int. Cl. C23C 14/06; C23C 28/04

(52) U.S. Cl. CPC C23C 14/0676; C23C 28/04

(57) ABSTRACT

An apparatus, such as an electronic device, may have a polymer substrate or layer, and a coating on the polymer substrate/layer. The coating may include an interfacial layer and a ceramic multilayer hard coat on the interfacial layer. The interfacial layer may be a non-nitride material, such as an oxide material, that is applied to the polymer substrate/layer. The ceramic multi-layer hard coat may be sputtered onto the interfacial layer and may include alternating nitride layers (e.g., oxynitride layers) with tensile stress and compressive stress. The presence of the interfacial layer may protect the polymer substrate/layer from damage during the sputtering of the ceramic multilayer hard coat.

This application claims the benefit of U.S. provisional patent application No. 63/698,429, filed Sep. 24, 2024, which is hereby incorporated by reference herein in its entirety.

### FIELD

This relates generally to substrates with coatings, including hard coatings.

### BACKGROUND

Apparatuses may include one or more transparent substrates and/or layers, such as cover layers for internal components. These transparent structures may be polymer substrates or polymer layers.

### SUMMARY

An apparatus, such as an electronic device, may have a polymer substrate or layer, and a coating on the polymer substrate/layer. For example, the apparatus may be a head-mounted device with a head-mounted support structure. Rear-facing displays may present images to eye boxes at the rear of the head-mounted support structure. A forward-facing publicly viewable display may be supported on a front side of the head-mounted support structure facing away from the rear-facing displays. The polymer substrate/layer may form a cover layer over the forward-facing publicly viewable display or may form another portion of the electronic device.

The coating may include an interfacial layer on the polymer substrate/layer and a ceramic multilayer hard coat on the interfacial layer. The interfacial layer may be a non-nitride layer, such as a layer formed from an oxide material, that is applied to the polymer substrate/layer. For example, the interfacial layer may be evaporable and may evaporated directly onto the polymer substrate/layer. Alternatively, the interfacial layer may be sputtered or otherwise deposited onto the polymer substrate/layer.

The ceramic multilayer hard coat may be sputtered onto the interfacial layer and may include alternating nitride layers (e.g., oxynitride layers) with tensile stress and compressive stress. The presence of the interfacial layer may protect the polymer substrate/layer from damage during the sputtering of the ceramic multilayer hard coat. If desired, the ceramic multilayer hard coat may have a balanced stress due to the alternating nitride layers.

### BRIEF DESCRIPTION OF THE DRAWINGS

FIG. 1 is a side view of an illustrative electronic device such as a head-mounted device in accordance with some embodiments.

FIG. 2 is schematic diagram of an illustrative system with an electronic device in accordance with some embodiments.

FIG. 3 is a front view of an illustrative head-mounted device in accordance with some embodiments.

FIG. 4 is a side view of an illustrative polymer substrate/layer with a ceramic multilayer hard coat and an intervening interfacial layer in accordance with some embodiments.

FIG. 5 is a side view of an illustrative ceramic multilayer hard coat that includes alternating nitride layers in accordance with some embodiments.

FIG. 6 is a side view of an illustrative ceramic multilayer hard coat with a portion that forms an antireflective (AR) coating in accordance with some embodiments.

FIG. 7 is a side view of an illustrative ceramic multilayer hard coat that includes a thick uppermost layer in accordance with some embodiments.

FIG. 8 is a flowchart of illustrative method steps of applying a ceramic multilayer hard coat and an interfacial layer on a polymer substrate/layer in accordance with some embodiments.

FIG. 9 is a side view of an illustrative coating applied to a curved polymer substrate/layer in accordance with some embodiments.

### DETAILED DESCRIPTION

An apparatus, such as an electronic device, may include a polymer substrate or layer, and a coating on the polymer substrate/layer. The coating may include an interfacial layer on the polymer substrate/layer and a ceramic multilayer hard coat on the interfacial layer. The interfacial layer may be a non-nitride layer, such as a layer formed from an oxide material, that is applied to the polymer substrate/layer. For example, the interfacial layer may be an evaporable, non-nitride layer, and may be evaporated directly onto the polymer substrate/layer. Alternatively, the interfacial layer may be sputtered or otherwise deposited on the polymer/substrate layer.

The ceramic multilayer hard coat may be sputtered onto the interfacial layer and may include alternating nitride layers (e.g., oxynitride layers) with tensile stress and compressive stress. The presence of the interfacial layer may protect the polymer substrate/layer from damage during the sputtering of the ceramic multilayer hard coat. If desired, the ceramic multilayer hard coat may have a balanced stress due to the alternating nitride layers.

In some embodiments, the apparatus may be a head-mounted device that includes a head-mounted support structure that allows the device to be worn on the head of a user. The head-mounted device may have displays that are supported by the head-mounted support structure for presenting a user with visual content. The displays may include rear-facing displays that present images to eye boxes at the rear of the head-mounted support structure. The displays may also include a forward-facing display. The forward-facing display may be mounted to the front of the head-mounted support structure and may be viewed by the user when the head-mounted device is not being worn on the user's head. The forward-facing display, which may sometimes be referred to as a publicly viewable display, may also be viewable by other people in the vicinity of the head-mounted device.

Optical components such as image sensors and other light sensors may be provided in the head-mounted device. In an illustrative configuration, optical components are mounted under peripheral portions of a display cover layer that protects the forward-facing display. The display cover layer, or other layers within the head-mounted device, may be formed from a polymer substrate, such as a polycarbonate substrate.

To reduce scratching that may otherwise occur on the polymer substrate, a ceramic hard coat may be applied to the polymer substrate. In particular, an interfacial layer, such as an oxide interfacial layer, may be deposited on the polymer substrate, and a ceramic multilayer coating may be sputtered on the interfacial layer. In this way, the ceramic multilayer coating may protect the polymer substrate from scratching, and the interfacial layer may protect the polymer substrate when the ceramic multilayer coating is sputtered.

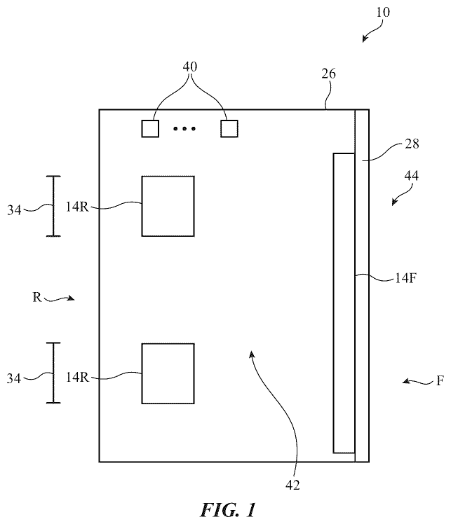

FIG. 1 is a side view of an illustrative apparatus that may include a polymer substrate to which a ceramic multilayer coating may be applied. In the illustrative example of FIG. 1, the apparatus is an electronic device and more specifically a head-mounted device. As shown in FIG. 1, head-mounted device 10 may include head-mounted support structure 26. Support structure 26 may have walls or other structures that separate an interior region of device 10 such as interior region 42 from an exterior region surrounding device 10 such as exterior region 44. Electrical components 40 (e.g., integrated circuits, sensors, control circuitry, light-emitting diodes, lasers, and other light-emitting devices, other control circuits and input-output devices, etc.) may be mounted on printed circuits and/or other structures within device 10 (e.g., in interior region 42).

To present a user with images for viewing from eye boxes such as eye boxes 34, device 10 may include rear-facing displays such as displays 14R, which may have associated lenses that focus images for viewing in the eye boxes. These components may be mounted in optical modules (e.g., a lens barrel) to form respective left and right optical systems. There may be, for example, a left rear-facing display for presenting an image through a left lens to a user's left eye in a left eye box and a right rear-facing display for presenting an image to a user's right eye in a right eye box. The user's eyes are located in eye boxes 34 at rear side R of device 10 when structure 26 rests against the outer surface of the user's face.

Support structure 26 may include a main support structure (sometimes referred to as a main portion or housing). The main housing support structure may extend from front side F of device 10 to opposing rear side R of device 10. On rear side R, support structure 26 may have cushioned structures to enhance user comfort as support structure 26 rests against the user's face. If desired, support structure 26 may include optional head straps and/or other structures that allow device 10 to be worn on a head of a user.

Device 10 may have a publicly viewable front-facing display such as display 14F that is mounted on front side F of support structure 26. Display 14F may be viewable to the user when the user is not wearing device 10 and/or may be viewable by others in the vicinity of device 10. Display 14F may, as an example, be visible on front side F of device 10 by an external viewer who is viewing device 10 from front side F.

Cover layer 28 may overlap display 14F. Cover layer 28 may be formed from polymer (e.g., polycarbonate), glass, sapphire, ceramic, and/or another transparent (or partially transparent) material. In some illustrative embodiments, cover layer 28 may be formed from a polymer substrate that is coated with a hard coat.

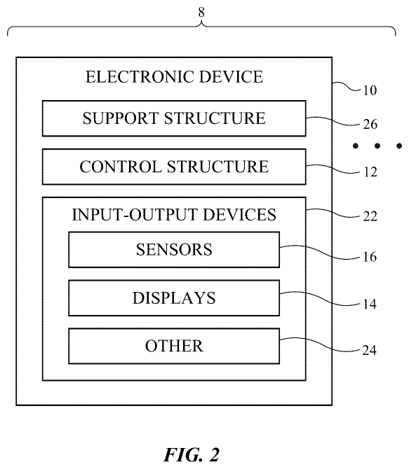

A schematic diagram of an illustrative system that may include an electronic device, such as a head-mounted device, is shown in FIG. 2. As shown in FIG. 2, system 8 may have one or more electronic devices 10. Devices 10 may include a head-mounted device (e.g., device 10 of FIG. 1), accessories such as controllers and headphones, computing equipment (e.g., a cellular telephone, tablet computer, laptop computer, desktop computer, and/or remote computing equipment that supplies content to a head-mounted device), a wearable electronic device, such as a wristwatch or ear buds, and/or other devices that communicate with each other.

Each electronic device 10 may have control circuitry 12. Control circuitry 12 may include storage and processing circuitry for controlling the operation of device 10. Circuitry 12 may include storage such as hard disk drive storage, nonvolatile memory (e.g., electrically-programmable-read-only memory configured to form a solid-state drive), volatile memory (e.g., static or dynamic random-access-memory), etc. Processing circuitry in control circuitry 12 may be based on one or more microprocessors, microcontrollers, digital signal processors, baseband processors, power management units, audio chips, graphics processing units, application specific integrated circuits, and other integrated circuits. Software code may be stored on storage in circuitry 12 and run on processing circuitry in circuitry 12 to implement control operations for device 10 (e.g., data gathering operations, operations involving the adjustment of the components of device 10 using control signals, etc.). Control circuitry 12 may include wired and wireless communications circuitry. For example, control circuitry 12 may include radio-frequency transceiver circuitry such as cellular telephone transceiver circuitry, wireless local area network transceiver circuitry, millimeter wave transceiver circuitry, and/or other wireless communications circuitry.

During operation, the communications circuitry of the devices in system 8 (e.g., the communications circuitry of control circuitry 12 of device 10) may be used to support communication between the electronic devices. For example, one electronic device may transmit video data, audio data, control signals, and/or other data to another electronic device in system 8. Electronic devices in system 8 may use wired and/or wireless communications circuitry to communicate through one or more communications networks (e.g., the internet, local area networks, etc.). The communications circuitry may be used to allow data to be received by device 10 from external equipment (e.g., a tethered computer, a portable device such as a handheld device or laptop computer, online computing equipment such as a remote server or other remote computing equipment, or other electrical equipment) and/or to provide data to external equipment.

Each device 10 in system 8 may include input-output devices 22. Input-output devices 22 may be used to allow a user to provide device 10 with user input. Input-output devices 22 may also be used to gather information on the environment in which device 10 is operating. Output components in input-output devices 22 may allow device 10 to provide a user with output and may be used to communicate with external electrical equipment.

As shown in FIG. 2, input-output devices 22 may include one or more displays such as displays 14. Displays 14 may include rear facing displays such as displays 14R of FIG. 1. Device 10 may, for example, include left and right components such as left and right scanning mirror display devices or other image projectors, liquid-crystal-on-silicon display devices, digital mirror devices, or other reflective display devices, left and right display panels based on light-emitting diode pixel arrays (e.g., thin-film organic light-emitting displays with polymer or semiconductor substrates such as silicon substrates or display devices based on pixel arrays formed from crystalline semiconductor light-emitting diode dies), liquid crystal display panels, and/or or other left and right display devices that provide images to left and right eye boxes for viewing by the user's left and right eyes, respectively. Display components such as these (e.g., a thin-film organic light-emitting display with a flexible polymer substrate or a display based on a pixel array formed from crystalline semiconductor light-emitting diode dies on a flexible substrate) may also be used in forming a forward-facing display for device 10 such as forward-facing display 14F of FIG. 1 (sometimes referred to as a front-facing display, front display, or publicly viewable display).

During operation, displays 14 (e.g., displays 14R and/or 14F) may be used to display visual content for a user of device 10 (e.g., still and/or moving images including pictures and pass-through video from camera sensors, text, graphics, movies, games, and/or other visual content). The content that is presented on displays 14 may, for example, include virtual objects and other content that is provided to displays 14 by control circuitry 12. This virtual content may sometimes be referred to as computer-generated content. Computer-generated content may be displayed in the absence of real-world content or may be combined with real-world content. In some configurations, a real-world image may be captured by a camera (e.g., a forward-facing camera, sometimes referred to as a front-facing camera) and computer-generated content may be electronically overlaid on portions of the real-world image (e.g., when device 10 is a pair of virtual reality goggles).

Input-output circuitry 22 may include sensors 16. Sensors 16 may include, for example, three-dimensional sensors (e.g., three-dimensional image sensors such as structured light sensors that emit beams of light and that use two-dimensional digital image sensors to gather image data for three-dimensional images from dots or other light spots that are produced when a target is illuminated by the beams of light, binocular three-dimensional image sensors that gather three-dimensional images using two or more cameras in a binocular imaging arrangement, three-dimensional lidar (light detection and ranging) sensors, sometimes referred to as time-of-flight cameras or three-dimensional time-of-flight cameras, three-dimensional radio-frequency sensors, or other sensors that gather three-dimensional image data), cameras (e.g., two-dimensional infrared and/or visible digital image sensors), gaze tracking sensors (e.g., a gaze tracking system based on an image sensor and, if desired, a light source that emits one or more beams of light that are tracked using the image sensor after reflecting from a user's eyes), touch sensors, capacitive proximity sensors, light-based (optical) proximity sensors, other proximity sensors, force sensors (e.g., strain gauges, capacitive force sensors, resistive force sensors, etc.), sensors such as contact sensors based on switches, gas sensors, pressure sensors, moisture sensors, magnetic sensors, audio sensors (microphones), ambient light sensors, flicker sensors that gather temporal information on ambient lighting conditions such as the presence of a time-varying ambient light intensity associated with artificial lighting, microphones for gathering voice commands and other audio input, sensors that are configured to gather information on motion, position, and/or orientation (e.g., accelerometers, gyroscopes, compasses, and/or inertial measurement units that include all of these sensors or a subset of one or two of these sensors), and/or other sensors.

User input and other information may be gathered using sensors and other input devices in input-output devices 22. If desired, input-output devices 22 may include other devices 24 such as haptic output devices (e.g., vibrating components), light-emitting diodes, lasers, and other light sources (e.g., light-emitting devices that emit light that illuminates the environment surrounding device 10 when ambient light levels are low), speakers such as ear speakers for producing audio output, circuits for receiving wireless power, circuits for transmitting power wirelessly to other devices, batteries and other energy storage devices (e.g., capacitors), joysticks, buttons, and/or other components.

As described in connection with FIG. 1, electronic device 10 may have head-mounted support structures such as head-mounted support structure 26 (e.g., head-mounted housing structures such as housing walls, straps, etc.). The head-mounted support structure may be configured to be worn on a head of a user (e.g., against the user's face covering the user's eyes) during operation of device 10 and may support displays 14, sensors 16, other components 24, other input-output devices 22, and control circuitry 12 (see, e.g., components 40 and displays 14R and 14F of FIG. 1, which may include associated optical modules).

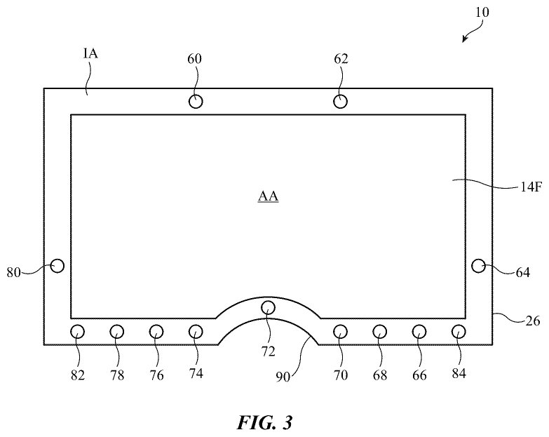

FIG. 3 is a front view of device 10 in an illustrative configuration in which device 10 has a publicly viewable display such as forward-facing display 14F. As shown in FIG. 3, support structure 26 of device 10 may have right and left portions on either side of nose bridge 90. Nose bridge 90 may be a curved exterior surface that is configured to receive and rest upon a user's nose to help support housing 26 on the head of the user.

Display 14F may have an active area such as active area AA that is configured to display images and an inactive area IA that does not display images. The outline of active area AA may be rectangular, rectangular with rounded corners, may have teardrop shaped portions on the left and right sides of device 10, may have a shape with straight edges, a shape with curved edges, a shape with a peripheral edge that has both straight and curved portions, and/or other suitable outlines. As shown in FIG. 3, active area AA may have a curved recessed portion at nose bridge 90. The presence of the nose-shaped recess in active area AA may help fit active area AA within the available space of housing 26 without overly limiting the size of active area AA.

Active area AA contains an array of pixels. The pixels may be, for example, light-emitting diode pixels formed from thin-film organic light-emitting diodes or crystalline semiconductor light-emitting diode dies (sometimes referred to as micro-light-emitting diodes) on a flexible display panel substrate. Configurations in which display 14F uses other display technologies may also be used, if desired. Illustrative arrangements in which display 14 is formed from a light-emitting diode display such as an organic light-emitting diode display that is formed on a flexible substrate (e.g., a substrate formed from a bendable layer of polyimide or a sheet of other flexible polymer) may sometimes be described herein as an example. The pixels of active area AA may be formed on a display device such as a display panel (e.g., a flexible organic light-emitting diode display panel). In some configurations, the outline of active area AA may have a peripheral edge that contains straight segments or a combination of straight and curved segments. Configurations in which the entire outline of active area AA is characterized by a curved peripheral edge may also be used.

Display 14F may have an inactive area such as inactive area IA that is free of pixels and that does not display images. Inactive area IA may form an inactive border region that runs along one or more portions of the peripheral edge of active area AA. In the illustrative configuration of FIG. 3, inactive area IA has a ring shape that surrounds active area AA and forms an inactive border. In this type of arrangement, the width of inactive area IA may be relatively constant and the inner and outer edges of area IA may be characterized by straight and/or curved segments or may be curved along their entire lengths. For example, the outer edge of area IA (e.g., the periphery of display 14F) may have a curved outline that runs parallel to the curved edge of active area AA.

In some configurations, device 10 may operate with other devices in system 8 (e.g., wireless controllers and other accessories). These accessories may have magnetic sensors that sense the direction and intensity of magnetic fields. Device 10 may have one or more electromagnets configured to emit a magnetic field. The magnetic field can be measured by the wireless accessories near device 10, so that the accessories can determine their orientation and position relative to device 10. This allows the accessories to wirelessly provide device 10 with real-time information on their current position, orientation, and movement so that the accessories can serve as wireless controllers. The accessories may include wearable devices, handled devices, and other input devices.

In an illustrative configuration, device 10 may have a coil that runs around the perimeter of display 14F (e.g., under inactive area IA along the periphery of active area AA). The coil may have any suitable number of turns (e.g., 1-10, at least 2, at least 5, at least 10, 10-50, fewer than 100, fewer than 25, fewer than 6, etc.). These turns may be formed from metal traces on a substrate, may be formed from wire, and/or may be formed from other conductive lines. During operation, control circuitry 12 may supply the coil with an alternating-current (AC) drive signal. The drive signal may have a frequency of at least 1 kHz, at least 10 kHz, at least 100 kHz, at least 1 MHz, less than 10 MHz, less than 3 MHz, less than 300 kHz, or less than 30 kHz (as examples). As AC current flows through the coil a corresponding magnetic field is produced in the vicinity of device 10. Electronic devices such as wireless controllers with magnetic sensors that are in the vicinity of device 10 may use the magnetic field as a reference so that the wireless controllers can determine their orientation, position, and/or movement while being moved relative to device 10 to provide device 10 with input.

Consider, as an example, a handheld wireless controller that is used in controlling the operation of device 10. During operation, device 10 uses the coil to emit a magnetic field. As the handheld wireless controller is moved, the magnetic sensors of the controller can monitor the location of the controller and the movement of the controller relative to device 10 by monitoring the strength, orientation, and change to the strength and/or orientation of the magnetic field emitted by the coil as the controller is moved through the air by the user. The electronic device can then wirelessly transmit information on the location and orientation of the controller to device 10. In this way, a handheld controller, wearable controller, or other external accessory can be manipulated by a user to provide device 10 with air gestures, pointing input, steering input, and/or other user input.

Device 10 may have components such as optical components (e.g., optical sensors among sensors 16 of FIG. 2). These components may be mounted in any suitable location on head-mounted support structure 26 (e.g. on a head strap, on housing 26, etc.). Optical components and other components may face rearwardly (e.g., when mounted on the rear face of device 10), may face to the side (e.g. to the left or right), may face downwardly or upwardly, may face to the front of device 10 (e.g., when mounted on the front face of device 10), may be mounted so as to point in any combination of these directions (e.g., to the front, to the right, and downward) and/or may be mounted in other suitable orientations. In an illustrative configuration, at least some of the components of device 10 are mounted so as to face outwardly to the front (and optionally to the sides and/or up and down). For example, forward-facing cameras for pass-through video may be mounted on the left and right sides of the front of device 10 in a configuration in which the cameras diverge slightly along the horizontal dimension so that the fields of view of these cameras overlap somewhat while capturing a wide-angle image of the environment in front of device 10. The captured image may, if desired, include portions of the user's surroundings that are below, above, and to the sides of the area directly in front of device 10.

To help hide components such as optical components from view from the exterior of device 10, it may be desirable to cover some or all of the components with cosmetic covering structures. The covering structures may include transparent portions (e.g., optical component windows) that are characterized by sufficient optical transparency to allow overlapped optical components to operate satisfactorily. For example, an ambient light sensor may be covered with a layer that appears opaque to an external viewer to help hide the ambient light sensor from view, but that allows sufficient ambient light to pass to the ambient light sensor for the ambient light sensor to make a satisfactory ambient light measurement. As another example, an optical component that emits infrared light may be overlapped with a visibly opaque material that is transparent to infrared light.

In an illustrative configuration, optical components for device 10 may be mounted in inactive area IA of FIG. 3 and cosmetic covering structures may be formed in a ring shape overlapping the optical components in inactive area IA. Cosmetic covering structures may be formed from ink, polymer structures, structures that include metal, glass, other materials, and/or combinations of these materials. In an illustrative configuration, a cosmetic covering structure may be formed from a ring-shaped member having a footprint that matches the footprint of inactive area IA. If, for example, active area AA has left and right portions with teardrop shapes, the ring-shaped member may have curved edges that follow the curved periphery of the teardrop-shaped portions of active area AA. The ring-shaped member may be formed from one or more polymer structures (e.g., the ring-shaped member may be formed from a polymer ring). Because the ring-shaped member can help hide overlapped components from view, the ring-shaped member may sometimes be referred to as a shroud or ring-shaped shroud member. The outward appearance of the shroud or other cosmetic covering structures may be characterized by a neutral color (white, black, or gray) or a non-neutral color (e.g., blue, red, green, gold, rose gold, etc.).

Display 14F may, if desired, have a protective display cover layer, such as cover layer 28 of FIG. 1. The cover layer may overlap active area AA and inactive area IA (e.g., the entire front surface of device 10 as viewed from front F of FIG. 1 may be covered by the cover layer). The cover layer, which may sometimes be referred to as a housing wall or transparent housing wall, may have a rectangular outline, an outline with teardrop portions, an oval outline, or other shape with curved and/or straight edges.

The cover layer may be formed from a transparent material such as glass, polymer, transparent crystalline material such as sapphire, clear ceramic, other transparent materials, and/or combinations of these materials. As an example, a protective display cover layer for display 14F may be formed from polymer, such as polycarbonate. Optional coating layers may be applied to the surfaces of the polymer display cover layer.

In active area AA, the display cover layer may overlap the pixels of display panel 14P. The display cover layer in active area AA is preferably transparent to allow viewing of images presented on display panel 14P. In inactive area IA, the display cover layer may overlap the ring-shaped shroud or other cosmetic covering structure. The shroud and/or other covering structures (e.g., opaque ink coatings on the inner surface of the display cover layer and/or structures) may be sufficiently opaque to help hide some or all of the optical components in inactive area IA from view. Windows may be provided in the shroud or other cosmetic covering structures to help ensure that the optical components that are overlapped by these structures operate satisfactorily. Windows may be formed from holes, may be formed from areas of the shroud or other cosmetic covering structures that have been locally thinned to enhance light transmission, may be formed from window members with desired light transmission properties that have been inserted into mating openings in the shroud, and/or may be formed from other shroud window structures.

In the example of FIG. 3, device 10 includes optical components such as optical components 60, 62, 64, 66, 68, 70, 72, 74, 76, 78, and 80 (as an example). Each of these optical components (e.g., optical sensors selected from among sensors 16 of FIG. 2, light-emitting devices, etc.) may be configured to detect light and, if desired to emit light (e.g., ultraviolet light, visible light, and/or infrared light). In some embodiments, these optical components may operate through a cover layer, such as cover layer 28 of FIG. 1.

In an illustrative configuration, optical component 60 may sense ambient light (e.g., visible ambient light). In particular, optical component 60 may have a photodetector that senses variations in ambient light intensity as a function of time. If, as an example, a user is operating in an environment with an artificial light source, the light source may emit light at a frequency associated with its source of wall power (e.g., alternating-current mains power at 60 Hz). The photodetector of component 60 may sense that the artificial light from the artificial light source is characterized by 60 Hz fluctuations in intensity. Control circuitry 12 can use this information to adjust a clock or other timing signal associated with the operation of image sensors in device 10 to help avoid undesired interference between the light source frequency and the frame rate or other frequency associated with image capture operations. Control circuitry 12 can also use measurements from component 60 to help identify the presence of artificial lighting and the type of artificial lighting that is present. In this way, control circuitry 12 can detect the presence of lights such as fluorescent lights or other lights with known non-ideal color characteristics and can make compensating color cast adjustments (e.g., white point adjustments) to color-sensitive components such as cameras and displays. Because optical component 60 may measure fluctuations in light intensity, component 60 may sometimes be referred to as a flicker sensor or ambient light frequency sensor.

Optical component 62 may be an ambient light sensor. The ambient light sensor may include one or more photodetectors. In a single-photodetector configuration, the ambient light sensor may be a monochrome sensor that measures ambient light intensity. In a multi-photodetector configuration, each photodetector may be overlapped by an optical filter that passes a different band of wavelengths (e.g. different visible and/or infrared passbands). The optical filter passbands may overlap at their edges. This allows component 62 to serve as a color ambient light sensor that measures both ambient light intensity and ambient light color (e.g., by measuring color coordinates for the ambient light). During operation of device 10, control circuitry 12 can take action based on measured ambient light intensity and color. As an example, the white point of a display or image sensor may be adjusted or other display or image sensor color adjustments may be made based on measured ambient light color. The intensity of a display may be adjusted based on light intensity. For example, the brightness of display 14F may be increased in bright ambient lighting conditions to enhance the visibility of the image on the display and the brightness of display 14F may be decreased in dim lighting conditions to conserve power. Image sensor operations and/or light source operations may also be adjusted based on ambient light readings.

The optical components in active area IA may also include components along the sides of device 10 such as components 80 and 64. Optical components 80 and 64 may be pose-tracking cameras that are used to help monitor the orientation and movement of device 10. Components 80 and 64 may be visible light cameras (and/or cameras that are sensitive at visible and infrared wavelengths) and may, in conjunction with an inertial measurement unit, form a visual inertial odometry (VIO) system.

Optical components 78 and 66 may be visible-light cameras that capture real-time images of the environment surrounding device 10. These cameras, which may sometimes be referred to as scene cameras or pass-through-video cameras, may capture moving images that are displayed in real time to displays 14R for viewing by the user when the user's eyes are located in eye boxes 34 at the rear of device 10. By displaying pass-through images (pass-through video) to the user in this way, the user may be provided with real-time information on the user's surroundings. If desired, virtual content (e.g. computer-generated images) may be overlaid over some of the pass-through video. Device 10 may also operate in a non-pass-through-video mode in which components 78 and 66 are turned off and the user is provided only with movie content, game content, and/or other virtual content that does not contain real-time real-world images.

Input-output devices 22 of device 10 may gather user input that is used in controlling the operation of device 10. As an example, a microphone in device 10 may gather voice commands. Buttons, touch sensors, force sensors, and other input devices may gather user input from a user's finger or other external object that is contacting device 10. In some configurations, it may be desirable to monitor a user's hand gestures or the motion of other user body parts. This allows the user's hand locations or other body part locations to be replicated in a game or other virtual environment and allows the user's hand motions to serve as hand gestures (air gestures) that control the operation of device 10. User input such as hand gesture input can be captured using cameras that operate at visible and infrared wavelengths such as tracking cameras (e.g., optical components 76 and 68). Tracking cameras such as these may also track fiducials and other recognizable features on controllers and other external accessories (additional devices 10 of system 8) during use of these controllers in controlling the operation of device 10. If desired, tracking cameras can help determine the position and orientation of a handheld controller or wearable controller that senses its location and orientation by measuring the magnetic field produced by coil 54. The use of tracking cameras may therefore help track hand motions and controller motions that are used in moving pointers and other virtual objects being displayed for a user and can otherwise assist in controlling the operation of device 10.

Tracking cameras may operate satisfactorily in the presence of sufficient ambient light (e.g., bright visible ambient lighting conditions). In dim environments, supplemental illumination may be provided by supplemental light sources such as supplemental infrared light sources (e.g., optical components 82 and 84). The infrared light sources may each include one or more light-emitting devices (light-emitting diodes or lasers) and may each be configured to provide fixed and/or steerable beams of infrared light that serve as supplemental illumination for the tracking cameras. If desired, the infrared light sources may be turned off in bright ambient lighting conditions and may be turned on in response to detection of dim ambient lighting (e.g., using the ambient light sensing capabilities of optical component 62).

Three-dimensional sensors in device 10 may be used to perform biometric identification operations (e.g., facial identification for authentication), may be used to determine the three-dimensional shapes of objects in the user's environment (e.g., to map the user's environment so that a matching virtual environment can be created for the user), and/or to otherwise gather three-dimensional content during operation of device 10. As an example, optical components 74 and 70 may be three-dimensional structured light image sensors. Each three-dimensional structured light image sensor may have one or more light sources that provide structured light (e.g., a dot projector that projects an array of infrared dots onto the environment, a structured light source that produces a grid of lines, or other structured light component that emits structured light). Each of the three-dimensional structured light image sensors may also include a flood illuminator (e.g., a light-emitting diode or laser that emits a wide beam of infrared light). Using flood illumination and structured light illumination, optical components 74 and 70 may capture facial images, images of objects in the environment surrounding device 10, etc.

Optical component 72 may be an infrared three-dimensional time-of-flight camera that uses time-of-flight measurements on emitted light to gather three-dimensional images of objects in the environment surrounding device 10. Component 72 may have a longer range and a narrower field of view than the three-dimensional structured light cameras of optical components 74 and 70. The operating range of component 72 may be 30 cm to 7 m, 60 cm to 6 m, 70 cm to 5 m, or other suitable operating range (as examples).

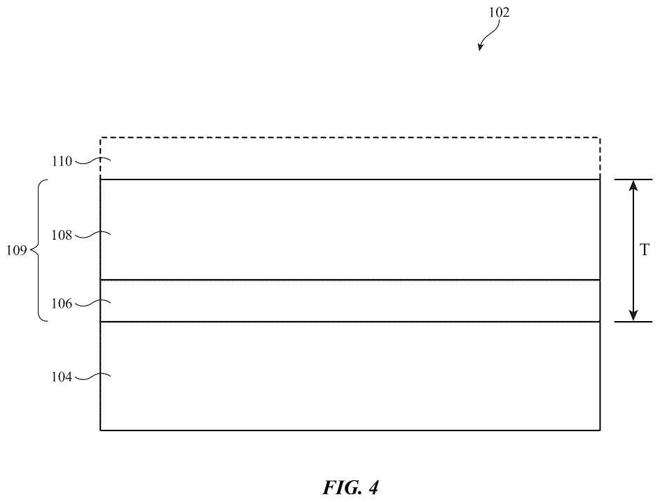

In general, it may be desirable to apply a hard coating to one or more polymer layers, such as to cover layer 28 of FIG. 1. For example, the hard coating may provide scratch protection and/or protection from other damage for cover layer 28. The hard coating may be formed from a ceramic material. However, sputtering the ceramic material directly onto a polymer layer may damage the polymer layer. Therefore, an interfacial layer may be included on the polymer layer between the polymer layer and the ceramic material to protect the polymer layer during deposition. An illustrative example is shown in FIG. 4.

As shown in FIG. 4, layer 102, which may be a cover layer (e.g., cover layer 28 of FIG. 1), may include polymer substrate 104 (also referred to as polymer layer 104 herein). Polymer substrate 104 may be a polycarbonate substrate or a substrate formed from another suitable polymer.

Coating 109 may be formed on polymer substrate 104. Coating 109 may include interfacial layer 106 directly on polymer substrate 104. Interfacial layer 106 may be formed from one or more oxides, such as aluminum oxide, silicon oxide, titanium oxide, zinc oxide, or zirconium oxide, as examples (e.g., interfacial layer 106 may be an oxide layer). In some illustrative embodiments, interfacial layer 106 may be formed from aluminum oxide (Al₂O₃) (e.g., interfacial layer 106 may be an aluminum oxide layer). In general, interfacial layer 106 may be formed from any suitable non-nitride material, such as a non-nitride oxide. In some embodiments, interfacial layer 106 may be an evaporable, non-nitride layer, such as an evaporable, non-nitride layer. However, this is merely illustrative. In general, interfacial layer 106 may be deposited onto polymer substrate 104 using any suitable process, such as evaporation, ion beam assisted deposition (IBAD), sol-gel deposition, post-laser deposition, atomic layer deposition, or sputtering.

Coating 109 may also include hard coat 108 formed on interfacial layer 106. Hard coat 108 may be formed from ceramic material (e.g., one or more nitrides). For example, hard coat 108 may be a multilayer hard coat formed from multiple, alternating nitride coatings (e.g., oxynitride coatings), such as SiON, AlON, SIN, AlN, and/or any other suitable nitrides. In some embodiments, hard coat 108 may having alternating nitride layers that exhibit compressive stress (e.g., SiON layers) and nitride layers that exhibit tensile stress (e.g., AlON layers). By alternating between nitride layers with compressive stress and nitride layers with tensile stress, hard coat 108 may have a balanced stress (e.g., a balanced combined stress of 0 MPa, or a balanced combined stress of less than 5 MPa, less than 10 MPa, or other suitable combined stress). Due to the balanced combined stress of hard coat 108, hard coat 108 may not warp and/or impart stress on substrate 104.

Because hard coat 108 is formed from one or more nitride layers, hard coat 108 is sputtered onto interfacial layer 106. In some embodiments, hard coat 108 may be sputtered onto interfacial layer 106 at a low temperature, such as less than 90° C., less than 100° C., less than 110° C., or another suitable low sputtering temperature. However, this is merely illustrative. Hard coat 108 may be sputtered at higher temperatures, if desired.

The presence of interfacial layer 106 may shield polymer substrate 104 from the plasma used to sputter hard coat 108. Because interfacial layer 106 is formed directly on polymer substrate 104, interfacial layer 106 may be formed from non-nitride material (e.g., one or more oxides). Additionally or alternatively, such as in embodiments in which interfacial layer 106 is formed from aluminum oxide, interfacial layer 106 may block ultraviolet light from damaging polymer substrate 104 during the sputtering of hard coat 108. In this way, damage to polymer substrate 104 may be reduced or eliminated by depositing interfacial layer 106 prior to sputtering hard coat 108.

Coating 109 may have thickness T. Thickness T may be at least one micron, at least two microns, at least four microns, less than 20 microns, between one micron and ten microns, as examples. Interfacial layer 106 may have a thickness of at least 20 nm, at least 40 nm, at least 60 nm, between 30 nm and 80 nm, 200 nm or less, between 50 nm and 200 nm, or another suitable thickness.

Optional layer(s) 110 may be formed on coating 109. Optional layer(s) 110 may include, for example, an antismudge layer (e.g., a fluoropolymer layer), an antireflection layer (e.g., one or more layers with an index of refraction between air and coating 109), and/or any other suitable layers.

In some embodiments, coating 109 may be a transparent, low haze coating on polymer substrate 104. For example, coating 109 may have a transparency of at least 70%, at least 80%, at least 95%, or at least 99%, as examples. Coating 109 may have a haze of less than 0.5%, less than 1%, or less than 0.3%, as examples. In this way, optical components, such as display 14F and/or optical sensors may operate through coating 109 on polymer substrate 104. However, in some embodiments, coating 109 may have less transparency, may exhibit a color (e.g., if hard coat 108 exhibits a color), or may have additional haziness. In general, interfacial layer 106 and/or hard coat 108 may be modified to have any suitable optical appearance.

In the example of FIG. 4, interfacial layer 106 is formed directly on substrate 104, and hard coat 108 is formed directly on interfacial layer 106. However, this is merely illustrative. If desired, one or more additional layers may be included between interfacial layer 106 and hard coat 108. In some embodiments, for example, layer 102 may include one or more polymer hard coats, one or more PVD coatings, and/or any other suitable layers between interfacial layer 106 and hard coat 108.

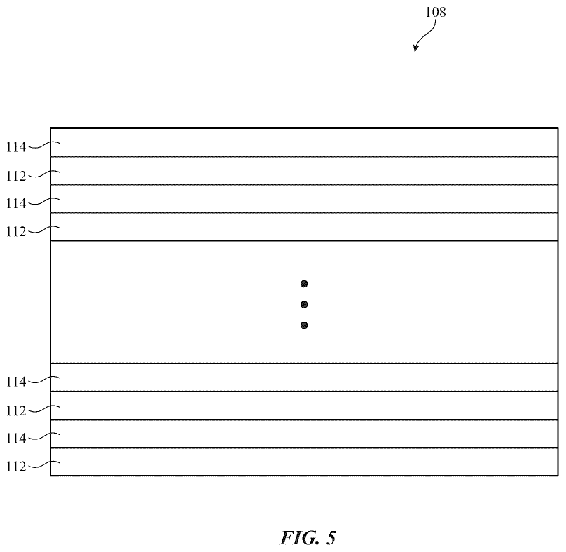

Hard coat 108 may be a multilayer ceramic hard coat. For example, hard coat 108 may include alternating nitride layers (e.g., oxynitride layers). An illustrative example is shown in FIG. 5.

As shown in FIG. 5, hard coat 108 may include layers 112 and layers 114. Layers 112 and 114 may alternate in a stack that forms hard coat 108 and may be formed of different nitride materials (e.g., oxynitride materials). For example, layers 112 may be formed from a first nitride material (e.g., a first oxynitride material) with tensile stress, such as AlON, while layers 114 may be formed from a second nitride material (e.g., a second oxynitride material) with compressive stress, such as SiON. By alternating between layers 114 with compressive stress and layer 112 with tensile stress, hard coat 108 may have a balanced stress (e.g., a combined zero stress, or a balanced combined stress of less than 5 MPa, less than 10 MPa, or other suitable combined stress). Due to the balanced stress of hard coat 108, hard coat 108 may not warp and/or impart stress on substrate 104 (FIG. 4).

In the example of FIG. 5, tensile layer 112 is the lowermost layer of hard coat 108 and may therefore be directly on (in direct contact with) interfacial layer 106 (FIG. 4). Compressive layer 114 is the uppermost layer of hard coat 108 and may therefore be directly in contact with optional layers 110. In some embodiments, compressive layer 114 may be directly in contact with an antismudge layer (e.g., a fluoropolymer layer) of optional layers 110. For example, if compressive layer 114 is formed from SiON, a fluoropolymer antismudge layer may be formed directly on the SiON. However, this arrangement is merely illustrative. In other embodiments, a tensile layer 112 may form the uppermost layer of hard coat 108 and/or a compressive layer 114 may form the lowermost layer of hard coat 108 and be in directly contact with substrate 104.

In general, hard coat 108 may include any suitable number of layers 112 and 114. For example, hard coat 108 may include at least one layer 112 and one layer 114, at least two layers 112 and two layers 114, at least four layers 112 and four layers 114, at least six layers 112 and six layers 114, or any other suitable number of layers 112 and layers 114.

Layers 112 and 114 may each have a thickness of less than 50 nm, less than 100 nm, between 20 nm and 200 nm, 5 microns or less, 2 microns or less, between 20 nm and five microns, or another suitable thickness. For example, layers 112 and 114 may be thin enough to avoid constructive and/or destructive interference of light through layers 112 and 114. However, this is merely illustrative. In some embodiments, layers 112 and 114 may be thicker to provide constructive and/or destructive interference of light through hard coat 108.

In the example of FIG. 5, layers 112 may have equal thicknesses (e.g., a first thickness) and layers 114 may have equal thicknesses (e.g., a second thickness). If desired, the first thickness (the thickness of layers 112) may be the same as the second thickness (the thickness of layers 114). However, this is merely illustrative. In some embodiments, the first thickness may be different from the second thickness.

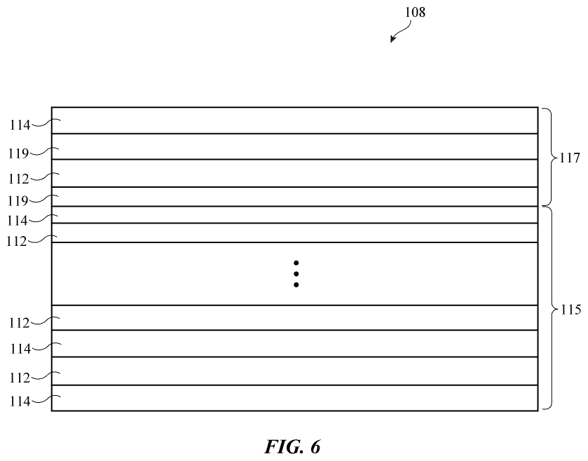

In some embodiments, layers 112 and 114 may provide optical interference. For example, layers 112 and 114 may have thicknesses and refractive indexes to destructively or constructively interfere with light incident on hard coat 108. This optical interference may provide hard coat 108 with a desired color, may reduce reflections from hard coat 108 (e.g., hard coat 108 may be an antireflective (AR coating), and/or may provide hard coat 108 with any other suitable optical properties. If desired, hard coat 108 may include additional layer(s) to form an AR coating with lower reflectivity. An illustrative example is shown in FIG. 6.

As shown in FIG. 6, portion 115 of hard coat 108, which may be formed directly on interfacial layer 106, may include alternating layers 112 and 114. In some illustrative embodiments, layers 112 may be AlON layers and layers 114 may be SiON layers. In general, however, layers 112 and 114 may be any suitable tensile and compressive layers, respectively. Each of layers 114 may have thicknesses of at least 40 nm, of less than 60 nm, of 50 nm, of between 40 nm and 60 nm, or other suitable thicknesses. Each of layers 112 may have thicknesses of at least 125 nm, of less than 175 nm, of 150 nm, of between 140 nm and 160 nm, or other suitable thicknesses. Portion 115 may have a thickness of at least 3 microns, at least 5 microns, between 4 microns and 6 microns, of 5 microns, of less than 7 microns, or another suitable thickness.

Portion 117 of hard coat 108 may form an AR coating. Therefore, portion 117 may be referred to as antireflective portion 117 herein. Portion 117 may form an outer portion of hard coat 108 (e.g., portion 115 may be interposed between portion 117 and interfacial layer 106—see FIG. 4). In particular, in addition to layers 112 and 114, portion 117 may include layers 119 interleaved with layers 112 and 114. Layers 119 may have low refractive indexes (e.g., refractive indexes less than 1.7, less than 1.6, between 1.5 and 1.6, or another suitable low refractive index). Therefore, layers 119 may be referred to as low-index layers 119 herein.

Low-index layers 119 may be formed from silicon dioxide or other low-index material(s). Low-index layers 119 may have a contrast in refractive index with layers 112 and 114. For example, layers 112 and 114 may have refractive indexes of at least 1.75, between 1.7 and 1.8, or another high index. The thicknesses of low-index layers 119 and the thickness of portion 117 may be tuned to reduce the reflections of hard coat 108. For example, low-index layers 119 may each have thicknesses of at least 40 nm, of less than 60 nm, of between 40 nm and 60 nm, of between 50 nm and 150 nm, of at least 125 nm, of less than 175 nm, of between 140 nm and 160 nm, or other suitable thicknesses. Portion 117 may have a thickness of at least 3 microns, at least 5 microns, of between 4 microns and 6 microns, of 5 microns, of less than 7 microns, or another suitable thickness. In general, the addition of low-index layers 119 in portion 117 of hard coat 108 produces optical interference, thereby reducing the reflections off of hard coat 108. Therefore, hard coat 108 may form an AR coating with the addition of low-index layers 119 in portion 117.

Although layers 119 have been described as low-index layers, this is merely illustrative. In some embodiments, if layers 112 and 114 are formed from low-index layers (e.g., layers with a refractive index of less than 1.7, less than 1.6, between 1.5 and 1.6, or another suitable low refractive index), layers 119 may be formed from high-index layers (e.g., layers with a refractive index of at least 1.75, between 1.7 and 1.8, or another high index). For example, layers 119 may be formed from niobium pentoxide or another suitable high-index material. By incorporating layers 119 with a refractive index that contrasts the refractive index of layers 112 and 114, the optical interference of hard coat 108 may be increased, and hard coat 108 may have improved anti-reflection properties.

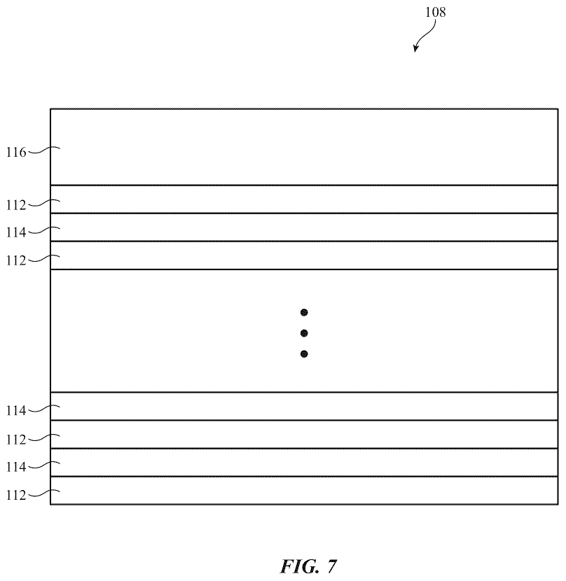

In some embodiments, an uppermost layer of hard coat 108 (or any other suitable layer in hard coat 108) may have a different thickness (e.g., a different thickness from the first thickness and the second thickness). An illustrative example is shown in FIG. 7.

As shown in FIG. 7, hard coat 108 may include uppermost layer 116. Uppermost layer 116 may be a nitride layer (e.g., an oxynitride layer) and may be the same material as layers 112 and/or layers 114. Alternatively, uppermost layer 116 may be another suitable ceramic layer, such as SiON, AlON, SIN, AlN, and/or any other suitable nitrides, or may be a non-ceramic layer.

Uppermost layer 116 may be thicker than layers 112 and/or layers 114. For example, uppermost layer 116 may have a thickness of at least one micron, at least two microns, less than 5 microns, between two microns and four microns, or another suitable thickness. In some embodiments, uppermost layer 116 may form an antireflection layer on the uppermost surface of hard coat 108 (e.g., uppermost layer 116 may have an index of refraction between air (or optional layers 110 of FIG. 4) and layers 112/114) and/or uppermost layer 116 may impart a color on hard coat 108 (e.g., uppermost layer 116 may be a colored layer, such as a layer that has been tinted with dye, pigment, or another suitable coloring). In this way, uppermost layer 116 may provide additional optical properties to hard coat 108.

Although FIG. 7 shows uppermost layer 116 having a different thickness from layers 112 and/or layers 114, this is merely illustrative. In general, thicker and/or thinner layers may be incorporated anywhere within hard coat 108. For example, layers 112 may have different thicknesses from one another and/or layers 114 may have different thicknesses from one another.

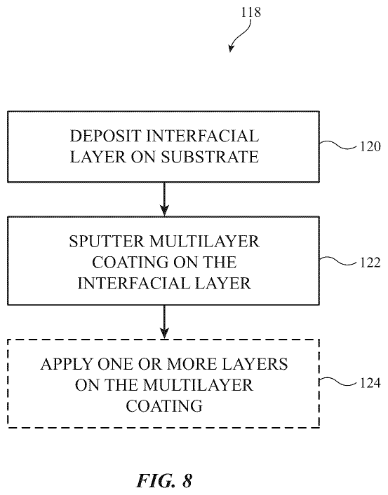

An illustrative example of a method in which a coating, such as coating 109 of FIG. 4, may be formed on a substrate is shown in FIG. 8.

As shown in FIG. 8, at step 120 of flowchart 118, an interfacial layer may be deposited on a substrate. For example, a non-nitride interfacial layer may be evaporated (e.g., using ion beam assisted deposition (IBAD) or another suitable process), sputtered, or otherwise deposited onto a polymer (e.g. polycarbonate) substrate or layer. The non-nitride interfacial layer may be formed from any suitable material, such as aluminum oxide or another suitable oxide.

At step 122, a multilayer hard coat may be sputtered onto the interfacial layer. The multilayer hard coat may be a multilayer ceramic hard coat that includes multiple nitrides with alternating tensile stress and compressive stress, such as AlON (e.g., AlON layers) and SiON (e.g., SiON layers). In some embodiments, one of the nitride layers with tensile stress (e.g., an AlON layer) may be applied directly to the interfacial layer. Because of the presence of the interfacial layer, the polymer substrate may not be damaged when the multilayer hard coat is sputtered onto the interfacial layer.

At step 124, one or more layers may be optionally applied to the multilayer coatings. These one or more optional layers may include an antismudge layer (e.g., a fluoropolymer layer), an antireflection layer (e.g., a layer with an index of refraction between air and the multilayer hard coat), and/or any other suitable layers.

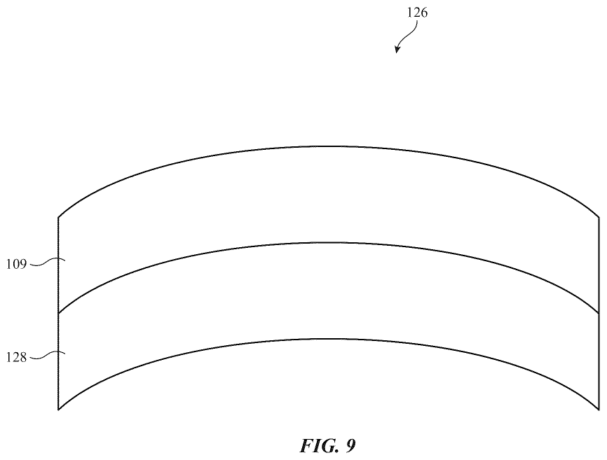

Although FIG. 4 shows polymer substrate 104 as a planar substrate, this is merely illustrative. In some embodiments, an interfacial layer and a multilayer hard coat may be applied to a curved substrate. An illustrative example is shown in FIG. 9.

As shown in FIG. 9, layer 126, which may be a cover layer (e.g., cover layer 28 of FIG. 1) may include curved polymer substrate 128. Curved polymer substrate 128 may be, for example, a polycarbonate substrate or a substrate of another suitable material.

Although the side view of layer 126 only shows curved polymer substrate 128 curved in one direction, this is merely illustrative. If desired, curved polymer substrate 128 may be curved in two different directions or three different directions. In other words, curved polymer substrate may exhibit compound curvature, if desired.

Coating 109 may be formed on curved polymer substrate 128. Coating 109 may include interfacial layer 106 and multilayer hard coat 108 (FIG. 4). Because coating 109 is deposited on curved polymer substrate 128 using evaporation, sputtering, or another suitable deposition for interfacial layer 106 and sputtering for multilayer hard coat 108, coating 109 may have a curvature that matches the curvature of curved polymer substrate 128. In this way, coating 109 may be formed a curved (e.g., three-dimensional) polymer substrate.

Although coating 109 has been described as being applied to a polymer substrate/layer in an electronic device, such as a head-mounted device, this is merely illustrative. In general, coating 109 may be applied to any suitable polymer substrate/layer in any suitable apparatus, any suitable electronic device, and/or any suitable system.

The foregoing is merely illustrative and various modifications can be made to the described embodiments. The foregoing embodiments may be implemented individually or in any combination.

What is claimed is:

1. Apparatus, comprising:
a polymer substrate; and
a coating on the polymer substrate, wherein the coating comprises:
an interfacial layer; and
a ceramic multilayer hard coat on the interfacial layer.

2. The apparatus of claim 1, wherein the interfacial layer comprises a non-nitride material.

3. The apparatus of claim 2, wherein the interfacial layer comprises an oxide material selected from the group consisting of: aluminum oxide, silicon oxide, titanium oxide, zirconium oxide, and zinc oxide.

4. The apparatus of claim 1, wherein the ceramic multilayer hard coat comprises a plurality of nitride layers.

5. The apparatus of claim 4, wherein the plurality of nitride layers comprises first oxynitride layers having tensile stress and second oxynitride layers having compressive stress.

6. The apparatus of claim 5, wherein the ceramic multilayer hard coat has a balanced combined stress of less than 5 MPa.

7. The apparatus of claim 5, wherein the first oxynitride layers comprise AlON layers and the second oxynitride layers comprise SiON layers.

8. The apparatus of claim 7, wherein a given one of the AlON layers forms a lowermost layer of the multilayer hard coat, and a given one of the SiON layers forms an uppermost layer of the multilayer hard coat.

9. The apparatus of claim 8, wherein the given one of the AlON layers is in direct contact with the interfacial layer.

10. The apparatus of claim 5, wherein the first oxynitride layers have first equal thicknesses and the second oxynitride layers have second equal thicknesses.

11. The apparatus of claim 10, wherein the first oxynitride layers and the second oxynitride layers each have thicknesses of less than 100 nm.

12. The apparatus of claim 11, wherein the coating has a thickness between one micron and ten microns.

13. The apparatus of claim 11, wherein the interfacial layer has a thickness between 50 nm and 200 nm.

14. The apparatus of claim 5, wherein the second oxynitride layers include layers of different thicknesses.

15. A method of coating a polymer substrate, the method comprising:
depositing an interfacial layer on the polymer substrate; and
sputtering a ceramic multilayer hard coat on the interfacial layer.

16. The method of claim 15, wherein depositing the interfacial layer comprises evaporating a non-nitride, oxide layer on the polymer substrate.

17. The method of claim 15, wherein sputtering the ceramic multilayer hard coat comprises sputtering alternating first nitride layers with tensile stress and second nitride layers with compressive stress in a stack on the interfacial layer.

18. The method of claim 17, wherein sputtering the ceramic multilayer hard coat comprises sputtering a given one of the first nitride layers directly on the interfacial layer.

19. Apparatus, comprising:
a polymer layer;
a non-nitride layer on the polymer layer; and
a ceramic multilayer hard coat comprising alternating first nitride layers with tensile stress and second nitride layers with compressive stress on the non-nitride layer.

20. The apparatus of claim 19, wherein the non-nitride layer comprises an aluminum oxide layer, the first nitride layers comprise AlON, and the second nitride layers comprise SiON.

21. The apparatus of claim 19, further comprising:
an antismudge layer on the ceramic multilayer hard coat, wherein the ceramic multilayer hard coat is interposed between the antismudge layer and the non-nitride layer.

22. The apparatus of claim 21, further comprising:
an additional layer interposed between the non-nitride layer and the ceramic multilayer hard coat.

23. The apparatus of claim 19, wherein the ceramic multilayer hard coat further comprises an antireflective portion that includes low-index layers interleaved with the first nitride layers and the second nitride layers.
